(19) United States
(12) Patent Application Publication
(10) Pub. No.: US 2019/0157328 A1
(43) Pub. Date: May 23, 2019

(54) IMAGE SENSOR, ELECTRONIC DEVICE AND MANUFACTURING METHOD THEREOF

(71) Applicant: HUAIAN IMAGING DEVICE MANUFACTURER CORPORATION, HUAIAN (CN)

(72) Inventors: Yosuke KITAMURA, HUAIAN (CN); Amane OISHI, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/010,143

(22) Filed: Jun. 15, 2018

(30) Foreign Application Priority Data
Nov. 22, 2017 (CN) 201711169197.1

(51) Int. Cl. H01L 27/146

(52) U.S. Cl. CPC H01L 27/14614; H04N 5/374; H01L 27/14689; H01L 27/14643

(57) ABSTRACT

In one or more exemplary embodiments, an image sensor comprises: a logic region, comprising a plurality of transistors; and a pixel region, comprising a plurality of pixel transistors; wherein a gate dielectric layer of a first pixel transistor in the plurality of pixel transistors is thinner than a gate dielectric layer of a first transistor in the plurality of transistors.

### CROSS-REFERENCE TO RELATED APPLICATIONS

This application claims priority to Chinese Patent Application No. 201711169197.1, filed on Nov. 22, 2017, which is hereby incorporated by reference in its entirety.

### TECHNICAL FIELD

The present disclosure relates to an image sensor and a manufacturing method thereof, and an electronic device comprising the image sensor and a manufacturing method thereof.

### BACKGROUND

Many modern electronic devices involve electronic devices using image sensors, such as single-lens reflex cameras, regular digital cameras, video cameras, mobile phones, and automobile electronics, etc. Accordingly, there is always a need in the art for image sensors with improved image quality.

### SUMMARY

One of the aims of the present disclosure is to provide a novel technology in the art.

An aspect of this disclosure may comprise at least one of an image sensor, a method of manufacturing the image sensor and an electronic device comprising the image sensor.

According to a first aspect of the present disclosure, there is provided an image sensor. The image sensor may comprise: a logic region, comprising a plurality of transistors; a pixel region, comprising a plurality of pixel transistors; wherein a gate dielectric layer of a first pixel transistor in the plurality of pixel transistors is thinner than a gate dielectric layer of a first transistor in the plurality of transistors.

According to a second aspect of the present disclosure, there is provided an electronic device. The electronic device may comprise the image sensor described above.

According to a third aspect of the present disclosure, there is provided a method of manufacturing an image sensor. The method may comprise: providing a substrate comprising a logic region and a pixel region; forming a gate dielectric layer at a surface of the substrate so that a gate dielectric layer in a first pixel transistor region of the pixel region is thinner than a gate dielectric layer in a first transistor region of the logic region.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 is a block diagram that illustrates a structural example of a part of an image sensor according to one or more exemplary embodiments of this disclosure.

FIG. 2 is a view that illustrates an image lag phenomenon in the image sensors.

FIG. 3 is a schematic cross-sectional view that illustrates a part of an image sensor according to one or more exemplary embodiments of this disclosure.

FIG. 4 is a view that illustrates improved image lag in an image sensor according to one or more exemplary embodiments of this disclosure.

FIG. 5 illustrates a flow chart of manufacturing an image sensor according to one or more exemplary embodiments of this disclosure.

FIGS. 6A-6E are cross-sectional views that illustrate a process of manufacturing a part of an image sensor according to one or more exemplary embodiments of this disclosure.

FIGS. 7A-7E are cross-sectional views that illustrate a process of manufacturing a part of an image sensor according to one or more exemplary embodiments of this disclosure.

FIGS. 8A-8E are cross-sectional views that illustrate a process of manufacturing a part of an image sensor according to one or more exemplary embodiments of this disclosure.

FIGS. 9A-9I are cross-sectional views that illustrate a process of manufacturing a part of an image sensor according to one or more exemplary embodiments of this disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of this disclosure unless it is specifically stated otherwise.

The following description of at least one exemplary embodiment is merely illustrative in nature and is in no way intended to limit this disclosure, its application, or uses.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

Currently, image sensors comprise pixel units arranged into a matrix array, each pixel unit including a number of photodiodes or other photosensitive elements and other elements (e.g., a reset transistor, an amplifying transistor, and a select transistor, etc.). Light incident upon an array of pixels is converted into electric charges by the photodiodes. After that, pixel signals corresponding to the electric charges generated after performing photoelectric conversion using the photodiodes are output from the respective pixel units. As is well known, the image sensors can be implemented using complementary metal oxide semiconductor (CMOS) circuits. This type of image sensors is generally called CMOS image sensors.

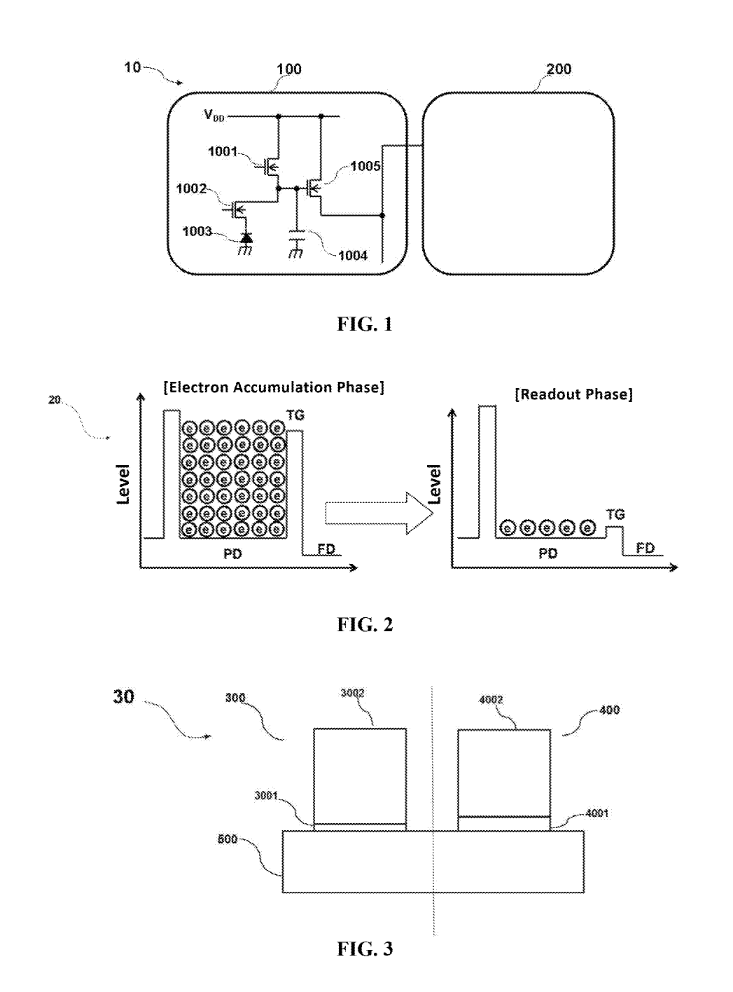

FIG. 1 is a block diagram that illustrates a structural example of a part of an image sensor 10 according to one or more exemplary embodiments of this disclosure. As shown in FIG. 1, the image sensor 10 may comprise a pixel region 100 and a logic region 200. FIG. 1 exemplarily illustrates the pixel region 100 comprises one pixel unit, but it can be understood by those skilled in the art that the pixel region 100 may comprise one or more other pixel units that are identical with or different from the pixel unit shown in FIG. 1. In the pixel region 100, the pixel unit comprises a reset transistor RST 1001, a transfer gate transistor TG 1002, a photodiode PD 1003, a floating diffusion portion FD 1004, and an amplifying transistor AMP 1005 (e.g., a source-follower transistor). The photodiode PD 1003 has an anode coupled to the ground and a cathode coupled to a source of the transfer gate transistor TG 1002. The transfer gate transistor TG 1002 has a drain coupled to a drain of the reset transistor RST 1001 and a gate of the amplifying transistor AMP 1005. A source of the reset transistor RST 1001 and a source of the amplifying transistor AMP 1005 are coupled to a power supply voltage V_{DD}. A drain of the amplifying transistor AMP 1005 is coupled to the logic region. Moreover, although the floating diffusion portion FD 1004 shown in FIG. 1 is a capacitor coupled at the drain of the reset transistor 1001, the drain of the transfer gate transistor 1002 and the gate of the amplifying transistor 1005, the disclosure is not limited to this. In one or more exemplary embodiments, the floating diffusion portion FD 1004 is a node at which the transfer gate transistor TG 1002, the reset transistor RST 1001, and the amplifying transistor AMP 1005 are coupled to one another.

In operation of the image sensor 10, the transfer gate transistor TG 1002 turns on or off transmission of the electric charges from the photodiode PD 1003 to the floating diffusion portion FD 1004 according to for example a drive signal provided by the logic region. For example, if the drive signal provided to the transfer gate transistor TG 1002 causes the transfer gate transistor TG 1002 be turned off, then the electric charges converted by the photodiode PD 1003 will be accumulated at the photodiode PD 1003; if the drive signal provided to the transfer gate transistor TG 1002 causes the transfer gate transistor TG 1002 be turned on, the electric charges will be allowed to be transmitted to the floating diffusion portion FD 1004.

The reset transistor RST 1001 determines whether to discharge the electric charges accumulated at the floating diffusion portion FD 1004 according to for example the drive signal provided by the logic region 200. For example, if the drive signal provided to the reset transistor RST 1001 causes the reset transistor RST 1001 to be turned on, then a level of the floating diffusion portion FD 1004 will be fixed to the power supply voltage V_{DD}, and the electric charges accumulated at the floating diffusion portion FD 1004 will be discharged (reset). Moreover, if the drive signal provided to the reset transistor RST 1001 causes the reset transistor RST 1001 to be turned off, the floating diffusion portion FD 1004 will be caused to be in an electrically floating state.

The amplifying transistor AMP 1005 amplifies a voltage corresponding to the electric charges accumulated at the floating diffusion portion FD 1004. Additionally, the pixel units in the pixel region 100 may further comprise a select transistor that is turned on or off to determine whether a pixel signal is output from the amplifying transistor AMP 1005 to the logic region 200. For example, if a drive signal provided to the select transistor causes it to be turned on, then the pixel signal will be output to the logic region 200, otherwise the pixel signal will be ceased to be output.

However, an arrangement of pixel units in CMOS image sensors is not limited to the structure shown in FIG. 1. In this disclosure, each pixel unit in an array of pixels of a CMOS image sensor may comprise one or more photodiodes PDs and transfer gate transistors TGs corresponding thereto. Each pixel unit may comprise its own floating diffusion portion FD; alternatively, a plurality of pixel units may share the floating diffusion portion FD. As an example of the latter arrangement, each of these pixel units comprises a transfer gate transistor TG for coupling the corresponding photodiode PD to the floating diffusion portion FD in a controllable manner during an image readout period. Further, in other embodiments, one or more of a reset transistor, an amplifying transistor and a select transistor can be shared among a plurality of pixel units.

Moreover, although the reset transistor RST 1001, the transfer gate transistor TG 1002 and the amplifying transistor AMP 1005 shown in FIG. 1 are PMOS transistors, this disclosure is not limited to this. These transistors can be any n-type devices or p-type devices that are capable of implementing the functions described above.

In one or more exemplary embodiments, the logic region 200 of the image sensor 10 may further comprise a circuit integrated by plural types of low-voltage transistors and high-voltage transistors and other elements, such as one or more of a signal amplifier, a column driver, a row selecting unit, a timing control logic, an AD converter, a data bus output structure, a control interface, an address decoder and an analog/digital conversion (ADC) circuit.

In one or more exemplary embodiments, the logic region 200 of the CMOS image sensor 10 may further comprise other processing circuits, such as processing circuits for auto exposure control, non-uniformity compensation, white balance processing, black level control, gamma correction, etc.

For clearly describing the aspects of this disclosure, these components included in the logic region 200 in the image sensor 10, which are well-known in the art, are omitted from being specifically described here.

However, in the CMOS image sensors, there may exist a plurality of factors that affect image quality, one of which is an image lag phenomenon due to the transfer gate transistor.

FIG. 2 is a view that illustrates an image lag phenomenon in the image sensors.

As described above, during an electron accumulation phase of the photodiode PD 1003, the transfer gate transistor TG 1002 is in an OFF state. Therefore, the level at the transfer gate transistor TG 1002 is high, and electrons will not be transmitted to the floating diffusion FD 1004, but be accumulated at the photodiode PD 1003.

During a readout phase of the photodiode PD 1003, the transfer gate transistor TG 1002 is in an ON state. Therefore, the level at the transfer gate transistor TG 1002 is low, and electrons can be transmitted from the photodiode PD 1003 to the floating diffusion portion FD 1004. However, if the transfer gate transistor TG 1002 has a weak modulation degree, the level at the transfer gate transistor TG 1002 cannot be reduced to be low enough so that part of the electrons remains at the photodiode PD 1003 and cannot sufficiently move to the floating diffusion portion FD 1004. Due to this circumstance, the image lag phenomenon occurs.

In order to improve the performance of image lag, it is necessary to improve the effectiveness of the transfer gate transistor TG 1002 in the pixel region 100.

In the CMOS image sensors, another important reason that affects image quality is random noise. Electric charges captured at a gate dielectric layer in an amplifying transistor are an important factor that causes random noise.

Thus, it is desired that random noise at the amplifying transistor AMP 1005 can be improved, thereby improving image quality of the image sensor 10.

Consequently, the inventor of the present application proposes a novel technology.

The inventor of the present application recognizes that, if the gate dielectric layer of the transfer gate transistor TG 1002 becomes thin, the modulation capability of the transfer gate transistor TG 1002 can be enhanced, so that the image lag phenomenon can be improved.

Moreover, the inventor of the present application further recognizes that, an important reason that generates random noise is that there exist captured electric charges at the substrate under the gate dielectric layer/gate dielectric layer of the amplifying transistor AMP 1005. Since the amount of electric charges captured is inversely proportional to capacitance of the gate dielectric layer per unit area, and the capacitance of the gate dielectric layer per unit area is inversely proportional to a thickness of the gate dielectric layer, thus random noise can be decreased by reducing the thickness of the gate dielectric layer. It can be seen that, if the thickness of the gate dielectric layer of the amplifying transistor AMP 1005 can be decreased, random noise of the image sensor 10 can be improved, thereby improving image quality of the image sensor 10.

The inventor of the present application finds that, compared with logic circuitry in the logic region, the pixel transistors (e.g., the transfer gate transistor TG 1002 and the amplifying transistor AMP 1005) have a relatively low duty ratio of voltage stress. Hence, at least one of advantages described above can be obtained by thinning the gate dielectric layer of the pixel transistors in the pixel region 100 of the image sensor 10.

FIG. 3 is a schematic cross-sectional view that illustrates a part of an image sensor 30 according to one or more exemplary embodiments of this disclosure. The image sensor 30 comprises a pixel region and a logic region, and in one or more exemplary embodiments shown in FIG. 3, the pixel region comprises a pixel transistor 300 and the logic region comprises a transistor 400, wherein the pixel transistor 300 for example may correspond to the transfer gate transistor TG 1002 or the amplifying transistor AMP 1005 shown in FIG. 1. It will be appreciated by those skilled in the art that, the pixel region and the logic region can respectively comprise one or more other transistors of the same type or of different types and other elements.

As shown in FIG. 3, the pixel transistor 300 and the transistor 400 are formed at a surface of a substrate 500, wherein the pixel transistor 300 may comprise a gate dielectric layer 3001 and a gate electrode 3002 and the transistor 400 may comprise a gate dielectric layer 4001 and a gate electrode 4002. The gate dielectric layer 3001 and the gate dielectric layer 4001 for example can be oxide layers (e.g., SiO₂, HfO₂, Al₂O₃, etc.), nitride layers (e.g., Si₃N₄, etc.) and organic layers (e.g., polyvinylidene fluoride (PVDF)). In one or more exemplary embodiments, the gate dielectric layer 3001 and the gate dielectric layer 4001 are oxide layers such as SiO₂ or HfO₂. The gate electrode 3002 and the gate electrode 4002 can be formed of a polysilicon or metal material. For the convenience of description, only the gate structure of the transistors is shown. But it should be appreciated by those skilled in the art that the pixel transistor 300 and the transistor 400 can further comprise other structures.

As shown in FIG. 3, the gate dielectric layer 3001 of the pixel transistor 300 is thinner than the gate dielectric layer 4001 of the transistor 400. In one or more exemplary embodiments, the pixel transistor 300 and the transistor 400 may have an identical operating voltage, which for example may be 2.5 to 3.3V. At this time, the thickness of the gate dielectric layer 3001 may be 4.0 to 5.5 nanometers, and the thickness of the gate dielectric layer 4001 may be 5.0 to 6.0 nanometers.

In one or more exemplary embodiments, the logic region may comprise a low-voltage transistor, an operating voltage of which for example may be 0.9 to 1.3 V. At this time, the low-voltage transistor may have a gate dielectric layer that is thinner than the pixel transistor 300, and for example, the thickness of the gate dielectric layer of the low-voltage transistor for example may be 1.5 to 2.5 nanometers.

It can be appreciated by those skilled in the art that the values mentioned above are only examples, and can be modified to other appropriate values according to actual needs.

Thus, in the image sensor of the present application, the gate dielectric layer of at least one of the transfer gate transistor or the amplifying transistor in the pixel region is at least thinner than the gate dielectric layer of a high-voltage transistor in the logic region. Moreover, in order to better improve image lag and random noise respectively, the thickness of the gate dielectric layer of the transfer gate transistor may be different from that of the gate dielectric layer of the amplifying transistor. Therefore, the image sensor may comprise, in the pixel region, the transfer gate transistor and the amplifying transistor having different gate dielectric layer thicknesses, and may comprise, in the logic region, the high-voltage transistor and the low-voltage transistor having different gate dielectric layer thicknesses, and hence the image sensor has a multi-gate structure. By means of this structure, image quality of the image sensor can be improved.

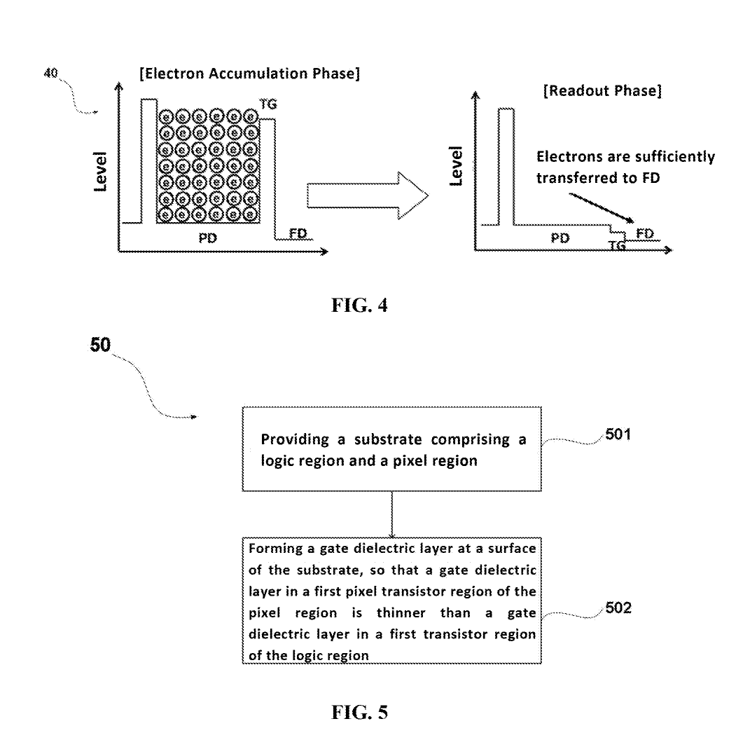

FIG. 4 is a view that illustrates improved image lag in an image sensor according to one or more exemplary embodiments of this disclosure.

In one or more exemplary embodiments of the present application, during the electron accumulation phase of the photodiode PD 1003, the transfer gate transistor TG 1002 is in the OFF state, and therefore, the level at the transfer gate transistor TG 1002 is high, and electrons will not be transmitted to the floating diffusion FD 1004, but be accumulated at the photodiode PD 1003. During the readout phase of the photodiode PD 1003, the transfer gate transistor TG 1002 is in the ON state, and therefore, the level at the transfer gate transistor TG 1002 is low, and electrons can be transmitted from the photodiode PD 1003 to the floating diffusion portion FD 1004. Since in one or more exemplary embodiments of the present application the gate dielectric layer of the transfer gate transistor TG 1002 is thinned, the modulation capability of the transfer gate transistor TG 1002 is enhanced so that the level at the transfer gate transistor TG 1002 is reduced to be low enough. Thus, the electrons will be sufficiently transferred from the photodiode PD 1003 to the floating diffusion portion FD 1004. Here, the term “sufficiently” means that the electrons are completely or substantially completely transferred from the photodiode to the floating diffusion portion. Alternatively, compared with the case in which the gate dielectric layer of the transfer gate transistor TG 1002 is not thinned, during the readout phase of the photodiode, the electrons that remain at the photodiode are removed or have a significantly reduced number. Consequently, the image lag phenomenon will be improved or eliminated.

FIG. 5 illustrates a flow chart of manufacturing an image sensor according to one or more exemplary embodiments of this disclosure. As shown in FIG. 5, at step 501, a substrate is provided, which comprises a logic region and a pixel region. The substrate may be a semiconductor substrate that is well-known in the art, such as a Si substrate, a Ge substrate or a SOI substrate, or the like. At step 502, a gate dielectric layer is formed at a surface of the substrate such that a gate dielectric layer in a first pixel transistor region of the pixel region is thinner than a gate dielectric layer in a first transistor region of the logic region. The gate dielectric layers can be formed using methods such as oxidation growth, deposition (e.g., chemical vapor deposition (CVD), physical vapor deposition (PVD), sputtering, or the like), etc. The gate dielectric layer in the first pixel transistor region of the pixel region can be made to become thinner than the gate dielectric layer in the first transistor region of the logic region using methods known in the art (e.g., photolithography, dry etching and wet etching).

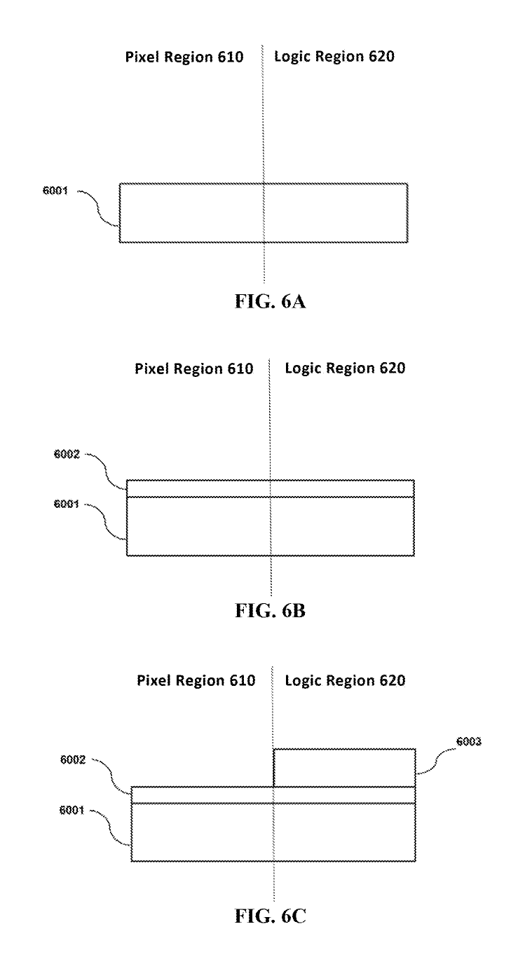

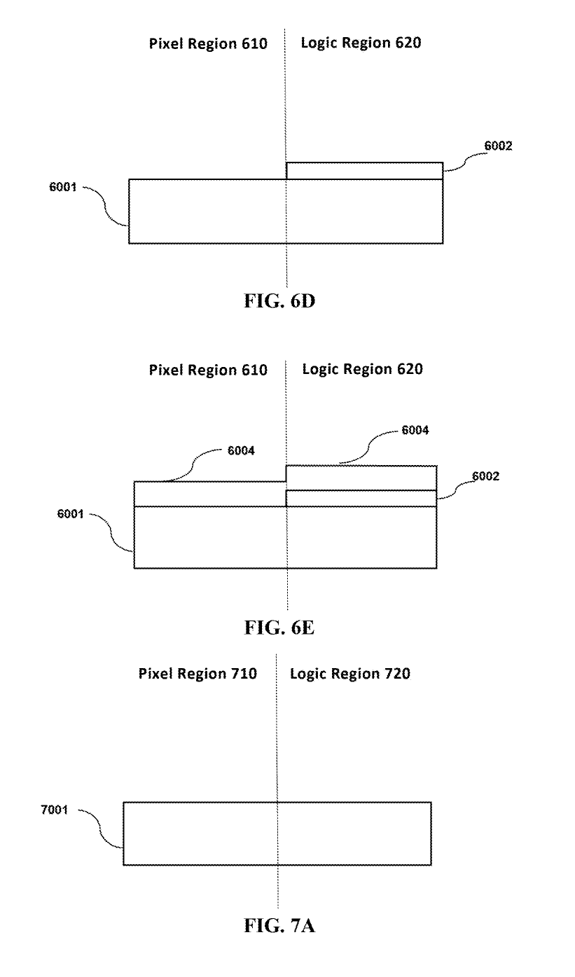

FIGS. 6A-6E are cross-sectional views that illustrate a process of manufacturing a part of an image sensor according to one or more exemplary embodiments of this disclosure. FIGS. 6A-6E are schematic cross-sectional views of a pixel region 610 and a logic region 620 each comprising a transistor, but it is appreciated by those skilled in the art that the pixel region 610 and the logic region 620 may comprise a plurality of transistors and other elements, and FIGS. 6A-6E are merely rendered for explanation. In the step of FIG. 6A, a substrate 6001 is provided, which comprises a pixel region 610 and a logic region 620. In the step of FIG. 6B, a first gate dielectric layer 6002 is formed on the substrate 6001, which can be formed using a method such as oxidation growth, deposition or the like. In the step of FIG. 6C, by a photolithography process, the first gate dielectric layer 6002 in the logic region 620 can be covered with a resist layer 6003, and the first gate dielectric layer 6002 in the pixel region 610 is exposed. In the step of FIG. 6D, the first gate dielectric layer 6002 in the pixel region 610 can be removed by etching, and after that, the resist layer 6003 is removed and the first gate dielectric layer 6002 in the logic region 620 is exposed. In the step of FIG. 6E, a second gate dielectric layer 6004 is formed on the substrate 6001 using a method such as deposition or the like, so that an overall thickness of the gate dielectric layer in the pixel region 610 is thinner than that of the gate dielectric layer in the logic region 620.

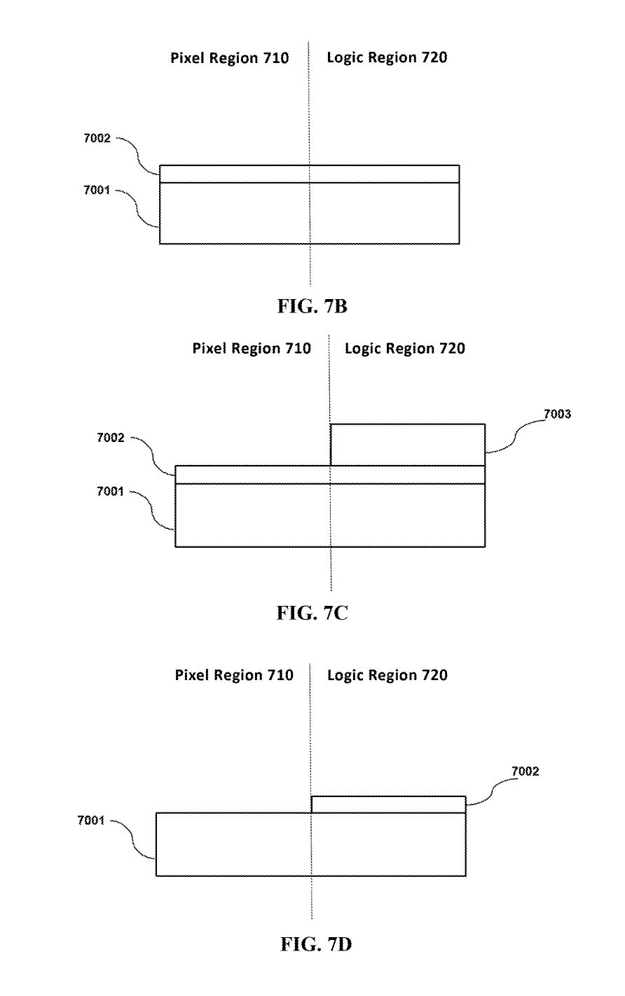

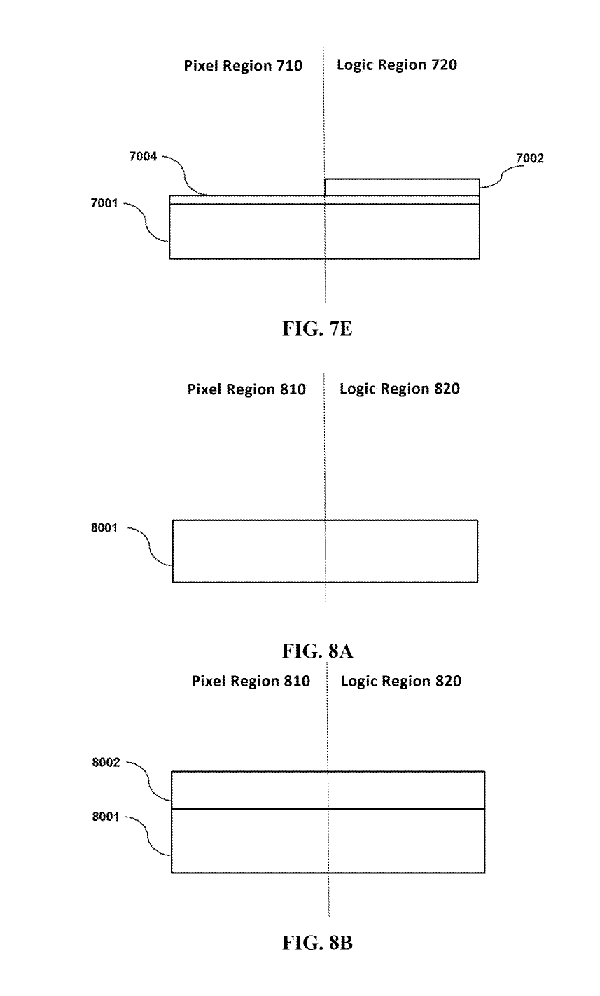

FIGS. 7A-7E are cross-sectional views that illustrate a process of manufacturing a part of an image sensor according to one or more exemplary embodiments of this disclosure. The steps of FIGS. 7A-7D can be similar to those of FIGS. 6A-6D. The method of this embodiment differs from the method illustrated in FIGS. 6A-6E in that, in the step of FIG. 7E, the second gate dielectric layer 7004 is formed using the oxidation growth method.

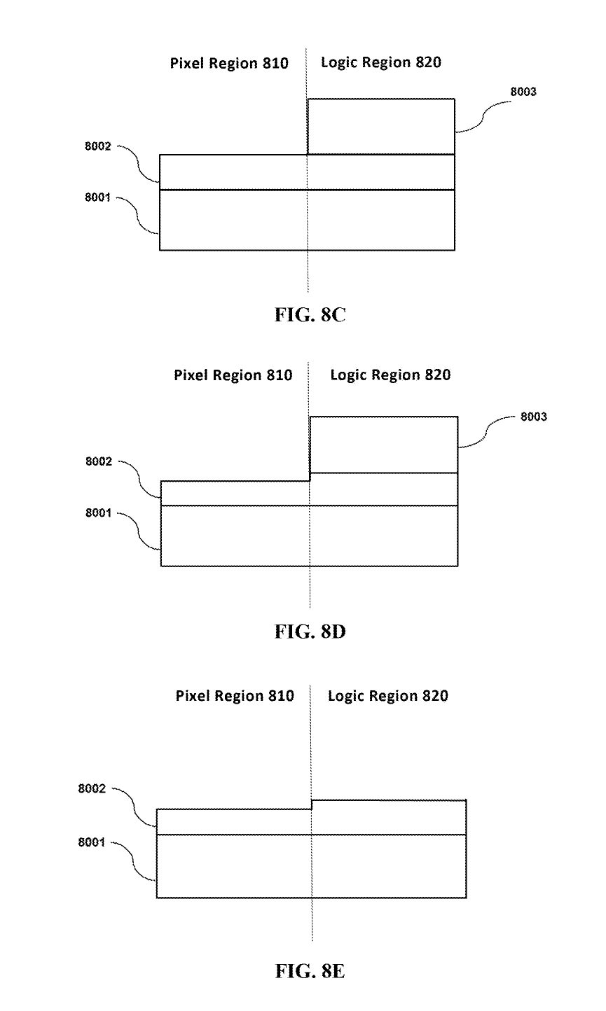

FIGS. 8A-8E are cross-sectional views that illustrate a process of manufacturing a part of an image sensor according to one or more exemplary embodiments of this disclosure. In the step of FIG. 8A, a substrate 8001 is provided, which comprises a pixel region 810 and a logic region 820. In the step of FIG. 8B, a gate dielectric layer 8002 is formed on the substrate 8001. The gate dielectric layer 8002 can be formed using a method such as deposition, oxidation growth, or the like. Generally, the gate dielectric layer 8002 can be formed to be thicker than the first gate dielectric layer 6002 shown in FIG. 6B and the first gate dielectric layer 7002 shown in FIG. 7B. In the step shown in FIG. 8C, by a photolithography process, a resist layer 8003 covers the gate dielectric layer 8002 in the logic region 820 and the gate dielectric layer 8002 in the pixel region 810 is exposed. Then, in the step shown in FIG. 8D, by an etching process, part of the gate dielectric layer 8002 in the pixel region 810 is removed. After that, in the step shown in FIG. 8E, the resist layer 8003 is removed.

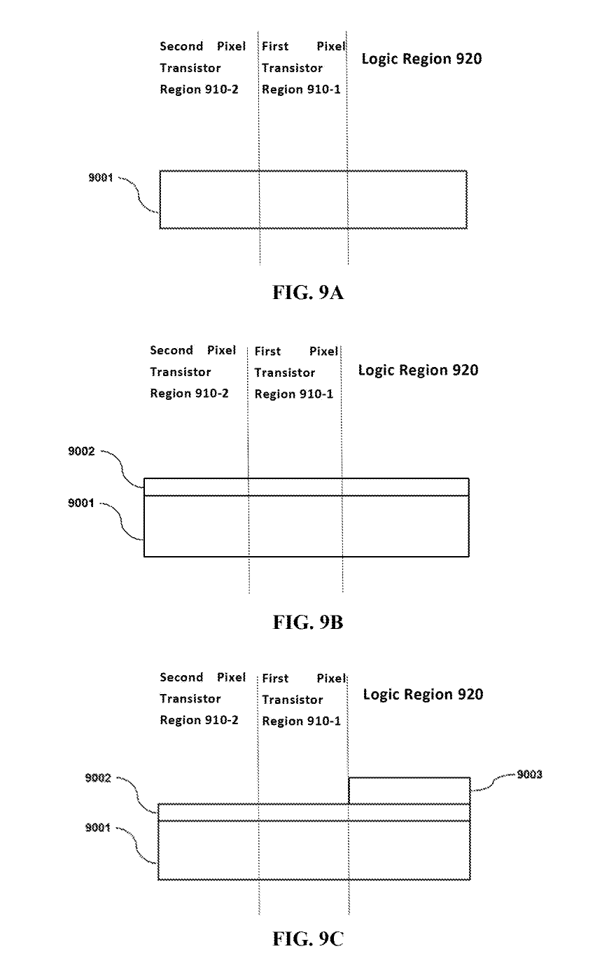

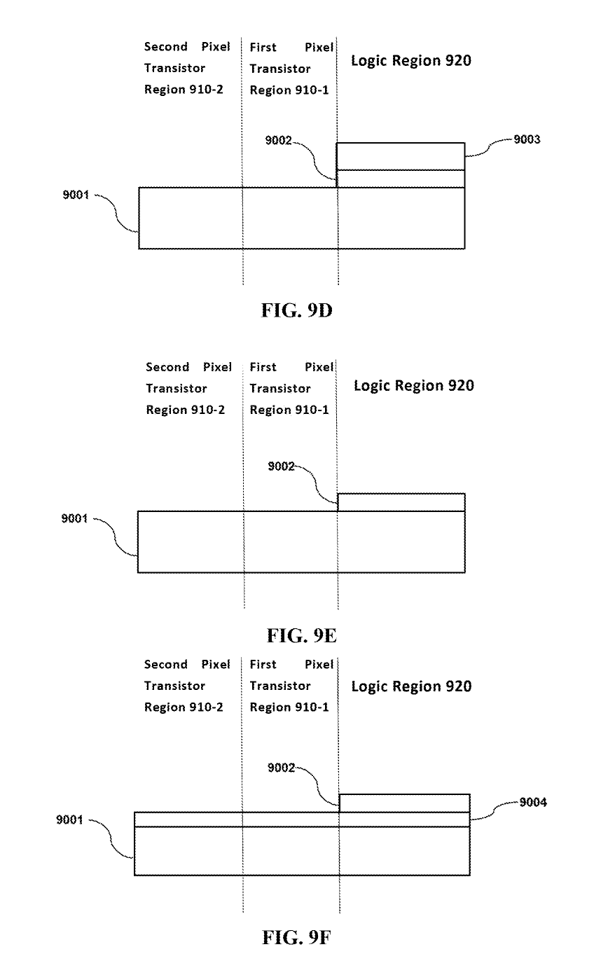

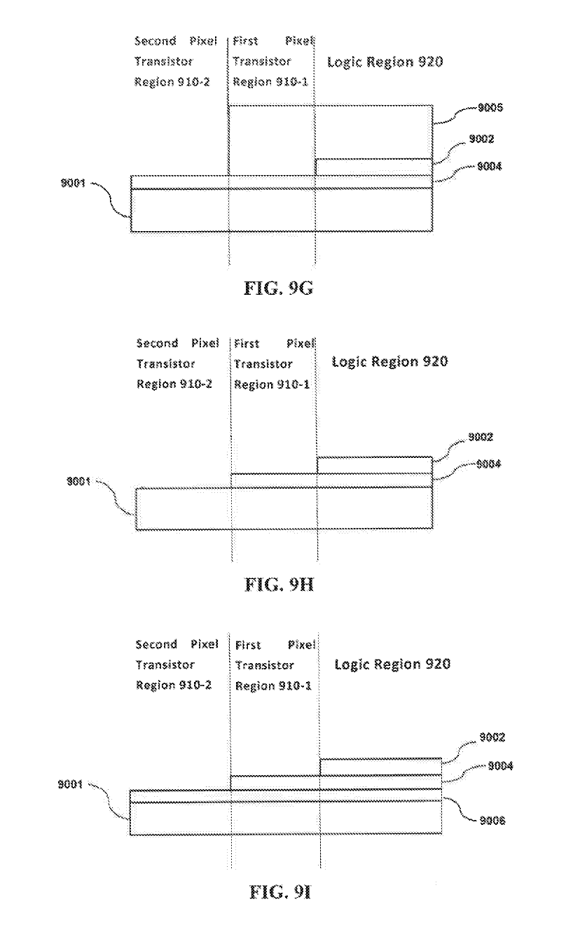

FIGS. 9A-9E are cross-sectional views that illustrate a process of manufacturing a part of an image sensor according to one or more exemplary embodiments of this disclosure.

In the step shown in FIG. 9A, a substrate 9001 is provided, which comprises a first pixel transistor region 910-1, a second pixel transistor region 910-2, and a logic region 920. In the step shown in FIG. 9B, a first gate dielectric layer 9002 is formed at a surface of the substrate. In the step of FIG. 9C, by the lithography process, a resist layer 9003 covers the first gate dielectric layer 9002 in the logic region 920, and the first gate dielectric layer 9002 in the first pixel transistor region 910-1 and the second pixel transistor region 910-2 is exposed. In the step shown in FIG. 9D, by the etching process, the first gate dielectric layer 9002 in the first pixel transistor region 910-1 and the second pixel transistor region 910-2 is removed, and the first gate dielectric layer 9002 in the logic region 920 is left. In the step shown in FIG. 9E, the resist layer 9003 is removed, and the first gate dielectric layer 9002 at the surface of the substrate in the logic region 920 is exposed.

In the step of FIG. 9F, a second gate dielectric layer 9004 is formed at the surface of the substrate 9001. In the embodiment shown in FIG. 9F, the second gate dielectric layer 9004 is formed using the oxidation growth method. However, it will be appreciated by those skilled in the art that the second gate dielectric layer 9004 can also be formed using other methods (e.g., deposition). In the step of FIG. 9G, by the lithography process, a resist layer 9005 covers the second gate dielectric layer 9004 in the first pixel transistor region 910-1 and the first gate dielectric layer 9002 and the second gate dielectric layer 9004 in the logic region 920, and the second gate dielectric layer 9004 in the second pixel transistor region 910-2 is exposed. In the step shown in FIG. 9H, by the etching process, the second gate dielectric layer 9004 exposed in the second pixel transistor region 910-2 is removed. After that, the resist layer 9005 is removed. In the step of FIG. 9I, a third gate dielectric layer 9006 is formed at the surface of the substrate 9001. As shown in FIG. 9I, the second pixel transistor region 910-2 comprises the third gate dielectric layer 9006, the first pixel transistor region 910-1 comprises the third gate dielectric layer 9006 and the second gate dielectric layer 9004, and the logic region 920 comprises the third gate dielectric layer 9006, the second gate dielectric layer 9004 and the first gate dielectric layer 9002. In this way, the image sensor having a multi-gate structure is formed.

As shown in FIG. 9I, in the pixel region 910, the gate dielectric layers in the first pixel transistor region 910-1 and in the second pixel transistor region 910-2 have different thicknesses. The transistor formed in the first pixel transistor region 910-1 is for example one of the transfer gate transistor or the amplifying transistor, and the transistor formed in the second pixel transistor region 910-2 is for example the other of the transfer gate transistor or the amplifying transistor. Moreover, the first pixel transistor region 910-1 and the second pixel transistor region 910-2 may also comprise pixel transistors of the same type, which are both for example the transfer gate transistors or the amplifying transistors. However, due to difference in the operating voltage or other reasons, their gate dielectric layers may also have different thicknesses.

The image sensors according to the embodiments of this disclosure may comprise CMOS image sensors and any other suitable sensors. Electronic devices according to the embodiments of this disclosure may comprise cameras, video cameras, and the like. The image sensors and electronic devices according to the embodiments can be used in many fields such as fields of mobile phones, computers, robots, monitoring, medical care, and automobiles, etc. In addition to the components mentioned above, the image sensor and the electronic device comprising the image sensor may further comprise component known in the art, such as a central processing unit (CPU), a memory (a nonvolatile memory and a volatile memory), and so forth.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor, comprising:
a logic region, comprising a plurality of transistors;
a pixel region, comprising a plurality of pixel transistors;
wherein a gate dielectric layer of a first pixel transistor in the plurality of pixel transistors is thinner than a gate dielectric layer of a first transistor in the plurality of transistors.

2. The image sensor according to claim 1,
wherein the gate dielectric layer of the first transistor has a thickness of 5 to 6 nanometers, and the gate dielectric layer of the first pixel transistor has a thickness of 4 to 5.5 nanometers.

3. The image sensor according to claim 1,
wherein an operating voltage of the first pixel transistor is identical with an operating voltage of the first transistor.

4. The image sensor according to claim 1,
wherein the plurality of pixel transistors further comprise a second pixel transistor, and a gate dielectric layer of the second pixel transistor is thinner than the gate dielectric layer of the first transistor in the plurality of transistors.

5. The image sensor according to claim 4,
wherein the gate dielectric layer of the second pixel transistor is thinner than the gate dielectric layer of the first pixel transistor.

6. The image sensor according to claim 4,
wherein the first pixel transistor is one of a transfer gate transistor or an amplifying transistor, and the second pixel transistor is the other of the transfer gate transistor or the amplifying transistor.

7. The image sensor according to claim 1,
wherein the pixel region further comprises a photodiode and a floating diffusion portion.

8. An electronic device, comprising an image sensor according to claim 1.

9. A method of manufacturing an image sensor, comprising:
providing a substrate comprising a logic region and a pixel region;
forming a gate dielectric layer at a surface of the substrate, so that a gate dielectric layer in a first pixel transistor region of the pixel region is thinner than a gate dielectric layer in a first transistor region of the logic region.

10. The method according to claim 9, wherein forming the gate dielectric layer at the surface of the substrate comprises:
forming a first gate dielectric layer at the surface of the substrate in the first transistor region of the logic region; and
forming a second gate dielectric layer at the surface of the substrate in the first pixel transistor region of the pixel region and the first transistor region of the logic region.

11. The method according to claim 9, wherein forming a gate dielectric layer at the surface of the substrate comprises:
forming a first gate dielectric layer at the surface of the substrate in the pixel region and in the logic region; and
thinning the first gate dielectric layer in the first pixel transistor region of the pixel region.

12. The method according to claim 9, wherein the gate dielectric layer is formed by a method of deposition or oxidation growth.

13. The method according to claim 9, wherein the pixel region further comprises a second pixel transistor region, and the step of forming a gate dielectric layer at the surface of the substrate further makes a gate dielectric layer in the second pixel transistor region also thinner than the gate dielectric layer in the first transistor region of the logic region.

14. The method according to claim 13, wherein the gate dielectric layer in the second pixel transistor region has a thickness smaller than a thickness of the gate dielectric layer in the first pixel transistor region, and the step of forming a gate dielectric layer at the surface of the substrate comprises:
forming a first gate dielectric layer at the surface of the substrate;
removing the first gate dielectric layer in the first pixel transistor region and the second pixel transistor region of the pixel region;
forming a second gate dielectric layer at the surface of the substrate;
removing the second gate dielectric layer in the first pixel transistor region; and
forming a third gate dielectric layer at the surface of the substrate.

15. The method according to claim 11, wherein thinning and removing are performed by a method of wet etching or dry etching.
